(19) United States
(12) Patent Application Publication
(10) Pub. No.: US 2012/0260986 A1
(43) Pub. Date: Oct. 18, 2012

(54) System for Switching Focus Position

(75) Inventors: Cheng-Huan Chen, Longtan/Taoyuan County (TW); Po-Hung Yao, Hsinchu (TW)

(73) Assignee: NATIONAL TSING HUA UNIVERSITY, Hsinchu (TW)

(21) Appl. No.: 13/409,094

(22) Filed: Feb. 29, 2012

(30) Foreign Application Priority Data
Apr. 15, 2011 (TW) 100113111

(51) Int. Cl. H01L 31/0232; G02F 1/133; F24J 2/04

(52) U.S. Cl. 136/259; 126/634; 349/1

(57) ABSTRACT

A system for switching a focus position comprises a plurality of active focus-switch devices capable of changing a focal length for several times, a plurality of objects to be focused, a plurality of incident light beams passing through the active focus-switch devices and then being focused on the objects to be focused, and at least one external power supply electrically connected to the active focus-switch devices, wherein the external power supply is electrically conducted or not conducted to the active focus-switch devices, and the plural incident light beams are focused on the objects to be focused by the active focus-switch devices, or the plural incident light beams passing through the active focus-switch device are projected to the outside in form of a plurality of exit light beams parallel to the plural incident light beams.

### BACKGROUND OF THE INVENTION

1. Field of the Invention

The present invention relates to a system for switching a focus position, in particular to the system that uses the relation between an external electric field and the tilt angle of liquid crystal molecules to switch the focus position.

2. Description of the Related Art

In the era of energy shortage, the demand for energy is much higher than the supply, and scientists and companies of the energy related industry spare no effort to find substitute energy sources. Up to now, solar energy is one of the newly developed substitute energies with the highest potential. Solar energy is inexhaustible. Compared with wind power generation and hydropower generation, solar energy can further generate heat energy. In Taiwan, leading companies of the solar energy related industry including E-Ton, Sino American Silicon, Neo Solar Power, and Solartech Energy, etc are committed to the development of solar batteries, and Epoch, Suncue, and Sun Water are committed to the development of solar water heaters. In foreign countries, U.S. Department of energy, major solar panel manufactures including First Solar, Solyndra, and Stion are committed to the development of solar energy and more states in the U.S. specifies a certain percentage of energy provided by renewable energies. The number of solar power stations in America is increasing.

In the development of solar energy, scientists is still trying to improve the utility of solar energy, and most prior arts break through the bottlenecks with regard to the heat energy or electrical energy, but there is no teaching on converting the solar energy into both heat energy and electrical energy. Related prior arts are elaborated below.

With reference to FIG. 5 for the representative drawing of a conventional solar light collection device as disclosed in R.O.C. Pat. No. M304644, the solar light collection device comprises a rack unit 1′, a plurality of solar panels 2′, a plurality of light collection panel 3′, a vapor chamber plate 4′, a power conversion unit 5′, a power storage unit 6′ and an erect device 7′; wherein the rack unit 1′ is mounted at a predetermined position by the erect unit 7′ to constitute a high-efficiency collection of a solar energy source at a solar collection plate of each solar chip, and the solar panel 2′ is formed by a plurality of arranged solar chips 21′, and a vapor chamber plate 4′ is installed on a distal surface of the solar panel 2′, and the light collection plate 3′ is formed by a plurality of arranged light collection plates 31′ for collecting light, and the light collection plates 31′ are light collection lens made of glass or acrylic, and each light collection plate 31′ is corresponsive to the solar chip 21′, so that each solar chip 21′ can collect a solar energy source through each light collection plate 31′ efficiently, and the power conversion unit 5′ is installed below the solar panel 2′ for converting the absorbed light and heat energy into electrical energy, and the power storage unit 6′ is installed below the solar panel 2′ and coupled to the power conversion unit 5′ for storing converted electrical energy. This patent improves the conventional light collection lens that cannot projected the collected sunlight at each solar energy absorption chip of a solar panel, so that the patent M304644 redesigns the solar energy light focusing device and the solar energy collection plates to provide a high-efficiency solar energy source collection effect for each solar chip.

With reference to FIG. 6 for a schematic view of a conventional solar energy focusing system without a tracer as disclosed in R.O.C. Pat. No. M372536, this patent comprises a solar chip 1″ and a curved optical focusing system 2″, wherein the solar chip 1″ can convert photon energy of a light 3″ projected onto a surface of the chip into electric energy by using a photoelectric effect, and the curved optical focusing system 2″ can be a small Fresnel lens array, and the optical axis of a small lens in each array is aligned precisely at the center of the sun in different time periods, and the common focus is situated on the solar chip 1″ for focusing lights 3″ with different incident angles onto the surface of the solar chip 1″, so as to enhance the utility of the light and reduce the layout area of the solar chip 1″. In addition, this patent does not require the use of any tracer to collect the lights from different angles and focus them at the solar chip 1″ effectively.

With reference to FIG. 7 for a representative drawing of a light energy collection system as disclosed in U.S. Pat. No. 7,612,285, the light energy collection system comprises a primary mirror 10″′ and a secondary mirror 14″′, and the primary mirror 10″′ has a concave surface 12″′ constructed and positioned to receive light energy and focus it towards a focal point; the secondary mirror 14″′ has a convex surface 16″′ constructed and positioned to receive the focused light energy from the primary mirror 10′″ and focus it onto an annular receiver 18″′, and the receiver 18″′ is installed between the primary mirror 10″′ and the secondary mirror 14″′, wherein the receiver 18′″ contains a set of energy conversion units, and the energy conversion units are used for generating heat energy or solar energy from the light source transmitted from the secondary mirror 14″′. With reference to FIG. 8 for a schematic view of a first preferred embodiment of U.S. Pat. No. 7,612,285, a heat exchanger 138′″ is provided for exchanging heat between liquids, a heat exchanger 140″′ is provided for exchanging heat between gas and liquid, a circulation pump 130″′ and a two-way selector solenoid valve 136″′. In the first preferred embodiment, the light energy collection system is connected to a heat energy storage unit, wherein the secondary mirror 14′″ generates heat energy after receiving the light reflected from the primary mirror 10″′. When water passes through the secondary mirror 14″′, the heat energy will be absorbed, and then the receiver 18″′ will transmit the heat to a heat energy storage device for storing the heat energy. With reference to FIG. 9 for a schematic view of a second preferred embodiment of a prior art as disclosed in U.S. Pat. No. 7,612,285, a vacuum chamber comprises a primary mirror 10″′, a metal evaporant source 72″′, a glass evaporant source 74′″, a filament 76′″, an anode 78′″, a plate 82′″, and an additional plate 84″′; the plate 82′″ is charged to a high voltage to accelerate the ionized evaporant and thereby impart extra energy to the evaporant stream. After the filament 76′″ is heated, electrons are released from the filament 76 and attracted by the anode 78″′ to generate a plurality of electron streams 80″′, so as to achieve the effect of generating electric energy by light energy.

With reference to FIGS. 10 and 11 for schematic views of a preferred embodiment of U.S. Pat. No. 6,256,153 and details thereof respectively, this patent relates to a circumscribing ray route lens system 1″″ for collecting and guiding incident light and comprises a lens section 2″″ and a transparent flat board 3″″, and the lens section 2″″ and the transparent flat board 3″″ are joined together in a side-by-side manner, and the lens section 2″″ comprises a ray receiver surface 2a″″, a transmitted light emitter surface 2b″″ and a total reflection surface 2f″″; wherein the ray receiver surface 2a″″ convex in shape is adapted to receive incident light, the total reflection surface 2f″″ is disposed between the ray receiver surface 2a″″ and the transmitted light emitter surface 2b″″, and the transmitted light emitter surface 2b″″ is further divided into three transmitted light emitter surfaces including a first transmitted light emitter surface 2e″″, a second transmitted light emitter surface 2d″″ and a third transmitted light emitter surface 2e″″. The transparent flat board 3″″ is provided for isolating dusts and facilitating wiping. This patent discloses an effective way of using sunlight, and a low-cost combinational lens, and one side of the lens is a Fresnel lens, and the other side has a plurality of convex lenses. In FIG. 11, the incident angle of sunlight varies with time, but this patent can receive equal quantity of sunlight, and the received quantity will not be affected by a different time.

In view of the aforementioned prior arts, there is no teaching on converting light energy into electrical energy and heat energy effectively, and these patented technologies can only convert light energy into either one of the electrical energy and heat energy only.

### SUMMARY OF THE INVENTION

Therefore, it is a primary objective of the present invention to provide a system for switching a focus position for generating heat energy and electrical energy, and improving the efficiency of collecting solar energy with the same sunlight.

A secondary objective of the present invention is to provide a system for switching a focus position for selectively converting the collected solar energy into electrical energy or heat energy when needed.

A tertiary objective of the present invention is to provide a system for switching a focus position for maintaining a space in a natural light condition by selectively and temporarily not collecting solar energy when lighting is not required.

To achieve the aforementioned objective, the present invention provides a system for switching a focus position, comprising: a plurality of active focus-switch devices, capable of changing a focal length for several times; a plurality of objects to be focused, having a plurality of exit light beams focused thereon after the plurality of incident light beams pass through the active focus-switch devices; and at least one external power supply, electrically coupled to active focus-switch device; wherein the external power supply is conducted or not conducted to the active focus-switch devices, and the active focus-switch devices can focus the plurality of exit light beams on the plurality of objects to be focused, or can form the plurality of exit light beams parallel to the plurality of incident light beams, after the plurality of incident light beams pass through the active focus-switch devices.

### BRIEF DESCRIPTION OF THE DRAWINGS

FIG. 1 is a schematic view of a system for switching a focus position in accordance with the present invention;

FIG. 2A is a schematic view, showing the principle of a focus mode of an active focus-switch device of a system for switching a focus position in accordance with the present invention;

FIG. 2B is a schematic view, showing the principle of a light transmission mode of an active focus-switch device of a focus mode of a system for switching a focus position in accordance with the present invention;

FIG. 3A is a schematic view of a system for switching a focus position in accordance with a first preferred embodiment of the present invention;

FIG. 3B is a schematic view of a system for switching a focus position in accordance with a first type of the first preferred embodiment of the present invention;

FIG. 3C is a schematic view of a system for switching a focus position in accordance with a second type of the first preferred embodiment of the present invention;

FIG. 3B is a schematic view of a system for switching a focus position in accordance with a third type of the first preferred embodiment of the present invention;

FIG. 4A is a schematic view of a micro-structure of a system for switching a focus position in accordance with a second preferred embodiment of the present invention;

FIG. 4B is a schematic view of a micro-structure of a system for switching a focus position in accordance with a third preferred embodiment of the present invention;

FIG. 5 is a representative drawing of a conventional solar light collection device as disclosed in R.O.C. Pat. No. M304644;

FIG. 6 is a schematic view of a conventional solar energy focusing system without a tracer as disclosed in R.O.C. Pat. No. M372536;

FIG. 7 is a representative drawing of a prior art as disclosed in U.S. Pat. No. 7,612,285;

FIG. 8 is a schematic view of a first preferred embodiment of a prior art as disclosed in U.S. Pat. No. 7,612,285;

FIG. 9 is a schematic view of a second preferred embodiment of a prior art as disclosed in U.S. Pat. No. 7,612,285;

FIG. 10 is a schematic view of a preferred embodiment of a prior art as disclosed in U.S. Pat. No. 6,256,153; and

FIG. 11 is a schematic view of details of a preferred embodiment of a prior art as disclosed in U.S. Pat. No. 6,256,153.

### DETAILED DESCRIPTION OF THE PREFERRED EMBODIMENTS

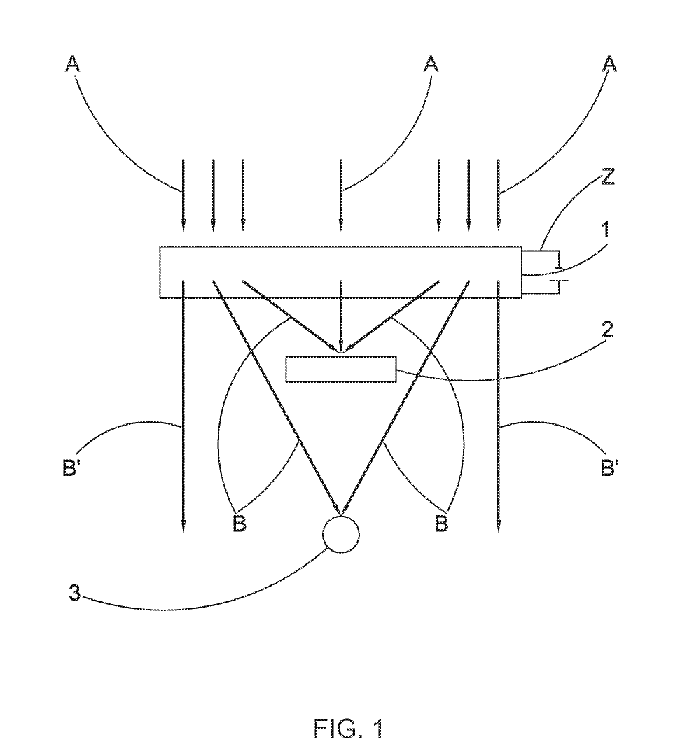

With reference to FIG. 1 for a schematic view of a system for switching a focus position in accordance with the present invention, the system for switching a focus position comprises: an active focus-switch device 1, for changing a focal length for several times, and the active focus-switch device including a focus-switch layer (not shown in the figure) and a micro-structure layer (not shown in the figure), and the focus-switch layer being covered onto the micro-structure layer; a plurality of objects to be focused 2, 3, having a plurality of exit light beams B formed after a plurality of incident light beams A pass through the active focus-switch device 1 and focused on the plurality of objects to be focused 2, 3; and at least one external power supply Z, electrically coupled to the active focus-switch device 1; wherein the external power supply Z is electrically conducted or not conducted to the active focus-switch device 1, and active focus-switch device 1 can focus the plurality of exit light beams B at the plurality of objects to be focused 2, 3, or emit an exit light beam B′ parallel to the incident light beam A after the plurality of incident light beams A pass through the active focus-switch device 1.

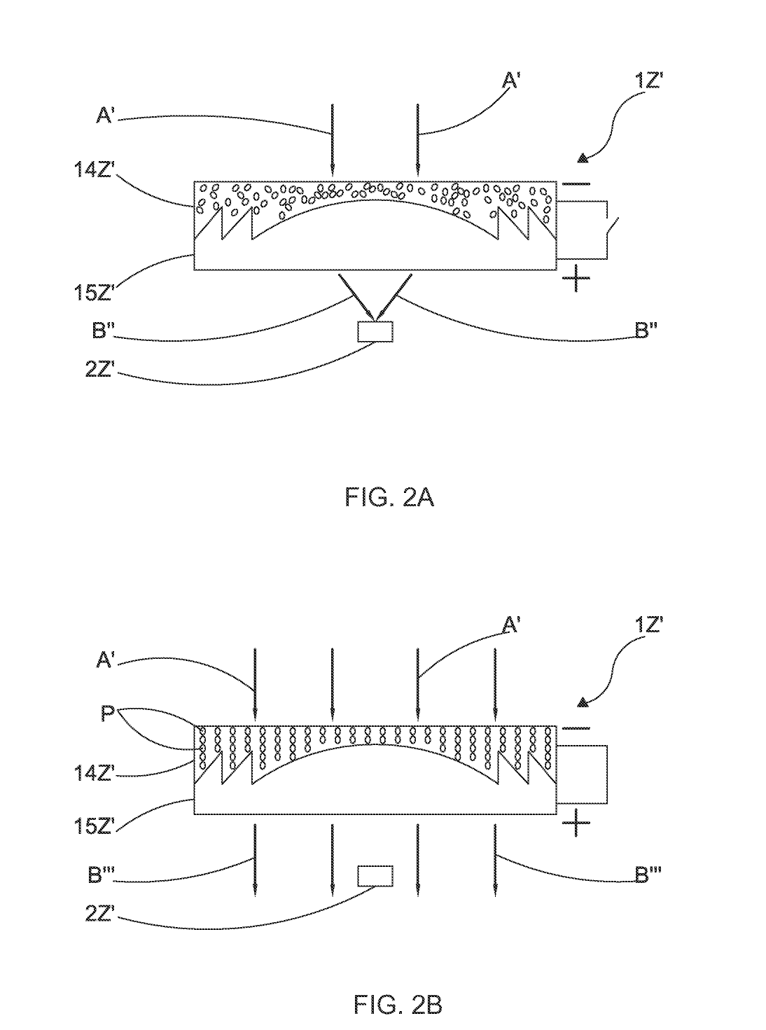

More specifically, with reference to FIGS. 2A and 2B for schematic views showing the principle of a focus mode and a light transmitting mode of an active focus-switch device of a system for switching a focus position in accordance with the present invention respectively, the active focus-switch device 1Z′ is covered onto a micro-structure by coating a liquid material (which can be a flat coating or a roll-to-roll coating process) or a perfusion process. By adjusting an external electric field, the directional arrangement of the liquid crystal molecules and the match rate of refraction between micro-structures can add a dynamic control function to the micro-structure originally having no flexibility for dynamically adjusting the optical properties for more diversified applications. In FIG. 2A, when there is on external electric field existed, the focus-switch layer (or the polymer dispersed liquid crystal layer, bistable liquid crystal layer or liquid crystal layer with reflective and refractive characteristics) 14Z′ have an equivalent refractive rate different from the refractive rate of the micro-structure (or the Fresnel lens) 15Z′, so that after the plurality of incident light beams A′ are scattered by the focus-switch layer 14Z′ and encountered with the micro-structure 15Z′, the incident light beams A′ will be affected and the plurality of exit light beams B″ are refracted and focused at an object to be focused 2Z′. In FIG. 2B, when the external electric field is applied, the liquid crystal molecules P of the focus-switch layer 14Z′ are affected by the electric field to show an alignment. Now, the equivalent refractive rate of the focus-switch layer 14Z′ is equal to the refractive rate of the micro-structure 15Z′, so that we cannot obtain the existence of a refraction interface when the plurality of incident light beams A′ are incident, so that the incident light beam A′ can pass through the active focus-switch device 1Z′ directly without being affected by the micro-structure 15Z′ and a plurality of parallel exit light beams B″′ can be emitted. Therefore, the active focus-switch device 1Z′ can have both focusing and non-focusing effects.

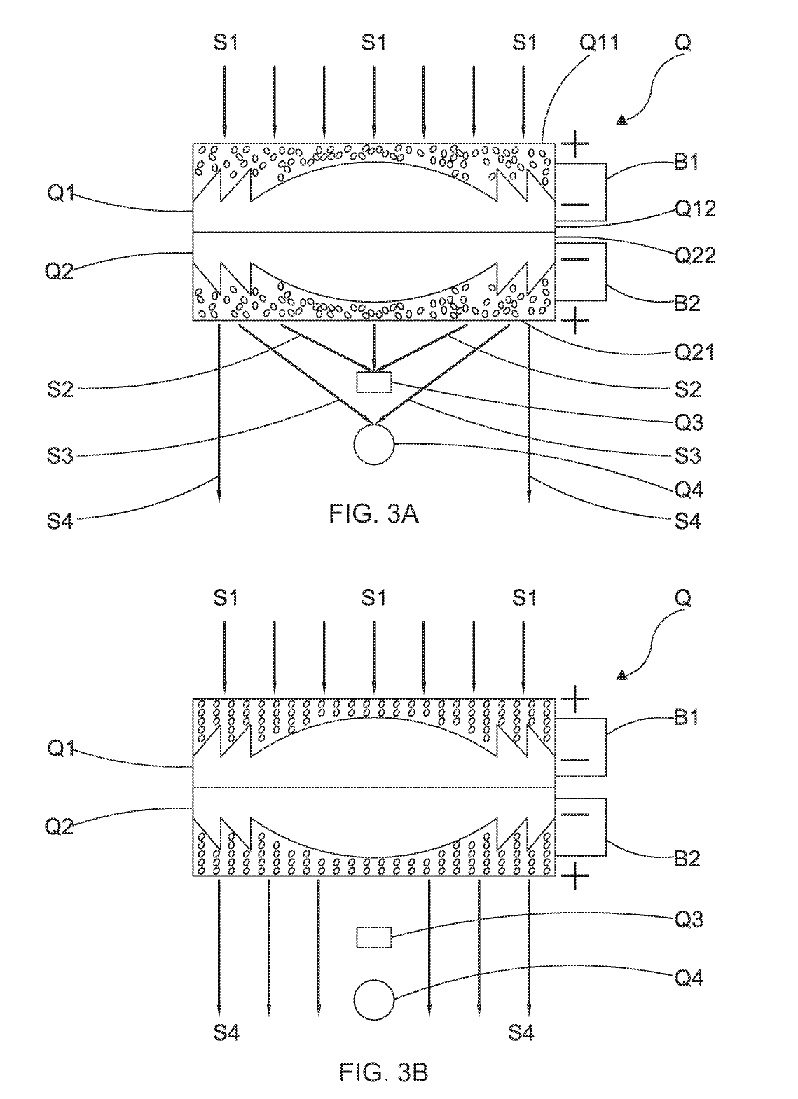

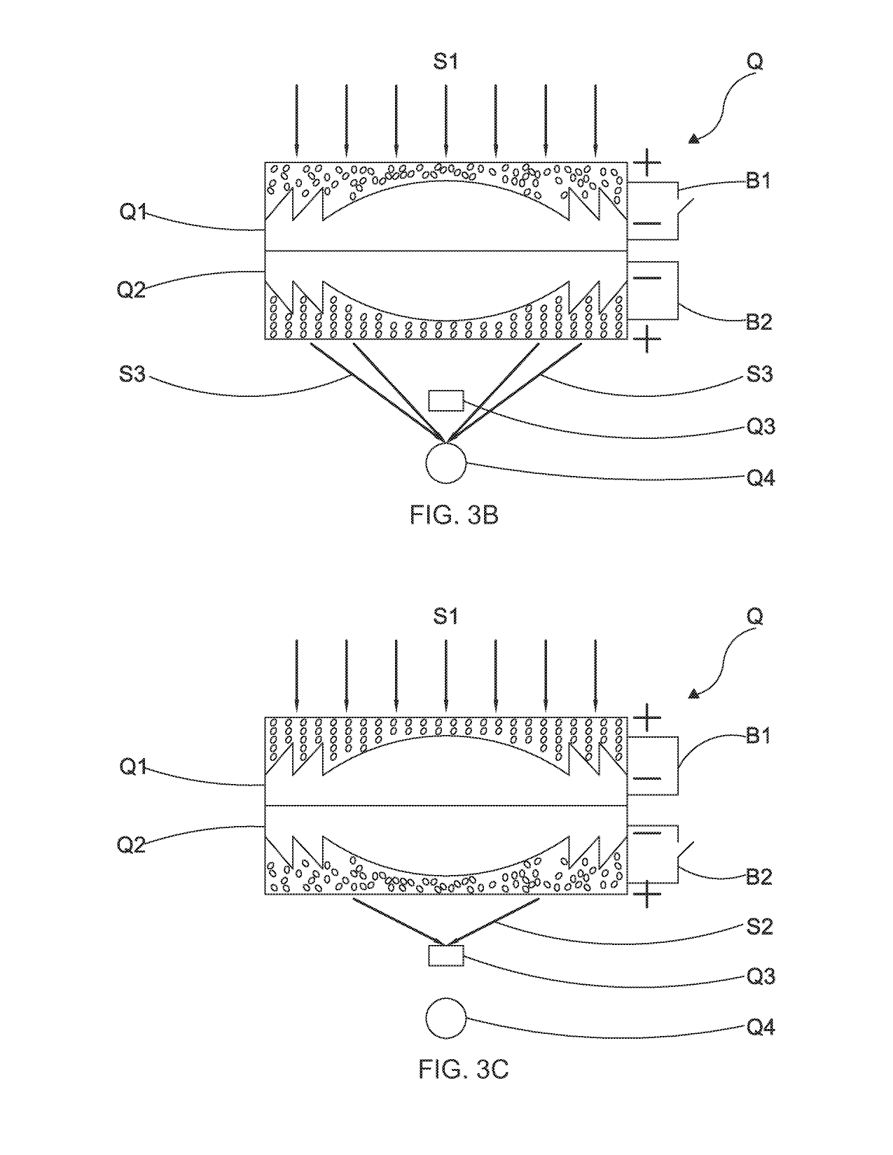

With reference to FIGS. 3A to 3D for schematic views of a system for switching a focus position in accordance with the first, second, third and fourth types of the first preferred embodiment of the present invention, the system for switching a focus position respectively, the system as shown in FIG. A comprises: an active focus-switch device Q, including a first active focus-switch lens Q1 and a second active focus-switch lens Q2 for changing a focal length for at least three times, and the first active focus-switch lens Q1 includes a first focus-switch layer Q11 and a first micro-structure layer Q12, and the first focus-switch layer Q11 is covered onto the first micro-structure layer Q12 by a general coating process, and the second active focus-switch lens Q2 includes a second focus-switch layer Q21 and a second micro-structure layer Q22, and the second focus-switch layer Q21 is covered onto the second micro-structure layer Q22 by a general coating process, and the first focus-switch layer Q11 and the second focus-switch layer Q21 are made of polymer dispersed liquid crystal (PDLC) or bistable liquid crystal, and the first micro-structure layer Q12 and the second micro-structure layer Q22 are primarily Fresnel lens structures; a first object to be focused Q3, a plurality of incident light beams S1 form a plurality of first exit light beams S2 after passing through the active focus-switch device Q and the plurality of first exit light beams S2 can be focused at the first object to be focused Q3, wherein the first object to be focused Q3 is a solar battery/photovoltaic device, for converting solar energy into electrical energy; a second object to be focused Q4, a plurality of incident light beams S1 form a plurality of second exit light beams S3 after passing the active focus-switch device Q, and the plurality of second exit light beams S3 can be focused onto the second object to be focused Q4, wherein the second object to be focused Q4 is a heating pipe for converting solar energy into heat energy; and two external power supplies, which are a first external power supply B1 and a second external power supply B2, and the first external power supply B1 and the second external power supply B2 are electrically coupled to the first active focus-switch lens Q1 and the second active focus-switch lens Q2 of the active focus-switch device Q; wherein the first active focus-switch lens Q1 and the second active focus-switch lens Q2 of the active focus-switch device Q are electrically conducted or not conducted by the first external power supply B1 and the second external power supply B2 respectively, and the active focus-switch device Q can focus the plurality of first exit light beams S2 onto the first object to be focused Q3, or focus the plurality of second exit light beams S3 onto the second object to be focused Q4, or emitting a plurality of third exit light beams S4 parallel to the plurality of incident light beams S1 by the incident light beam S1 after passing through the active focus-switch device Q.

In FIG. 3B, when the first external power supply B1 is not conducted to the first active focus-switch lens Q1, and the second external power supply B2 is conducted to the second active focus-switch lens Q2, a long focusing effect can be achieved, so that the second exit light beam S3 can be focused at the second object to be focused Q4.

In FIG. 3C, when the first external power supply B1 is conducted to the first active focus-switch lens Q1, and the second external power supply B2 is not conducted to the second active focus-switch lens Q2, a short focusing effect can be achieved, so that the first exit light beam S2 can be focused at the first object to be focused Q3.

In FIG. 3D, when the first external power supply B1 and the second external power supply B2 are conducted to the first active focus-switch lens Q1 and the second active focus-switch lens Q2 respectively, the plurality of third exit light beams S4 parallel to the incident light beam S1 are emitted, so that there will be no focusing.

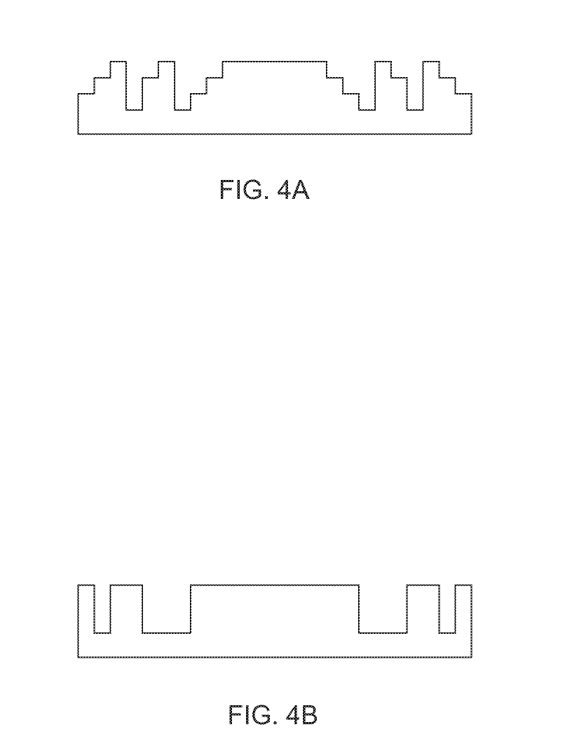

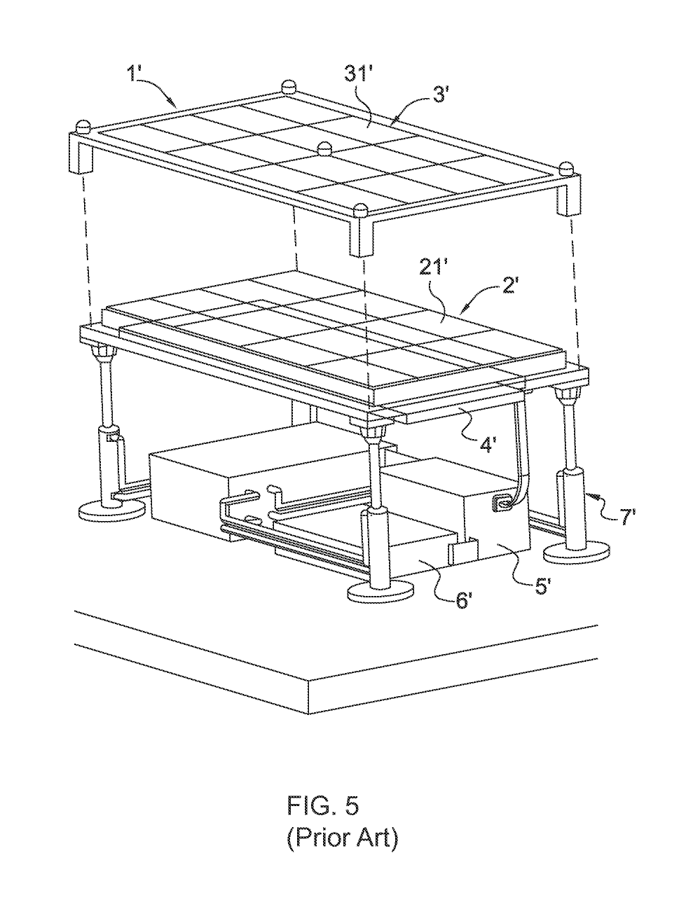

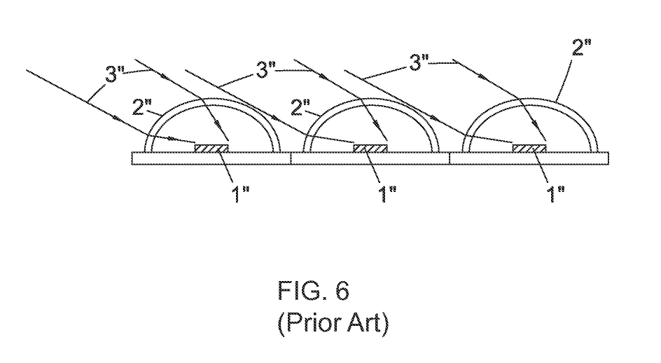

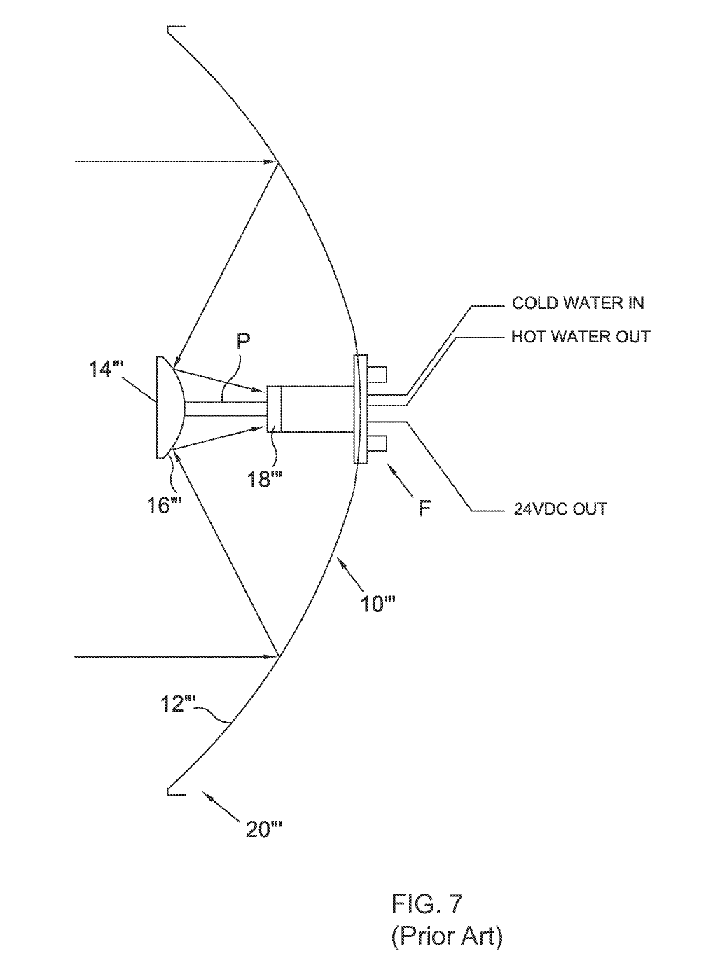

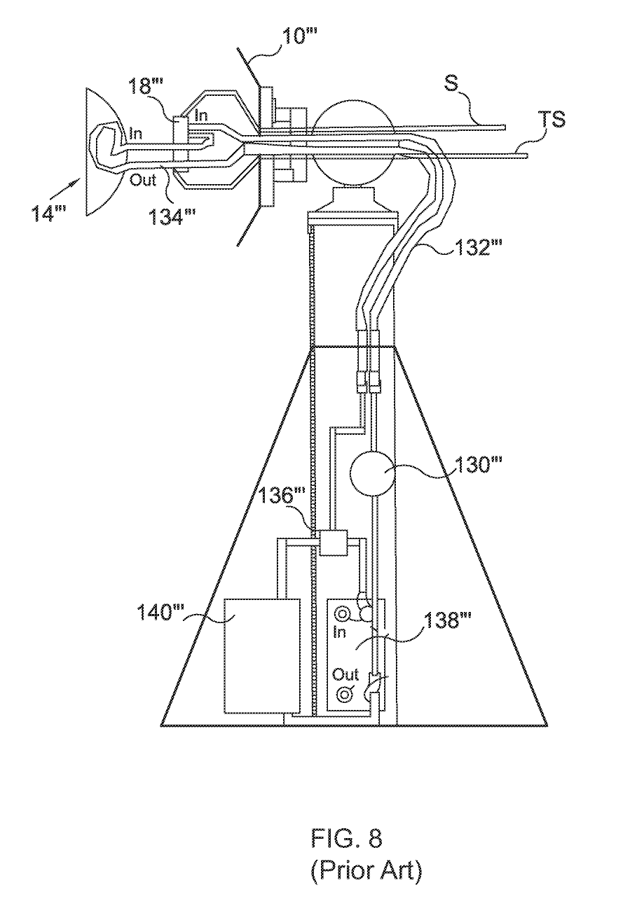

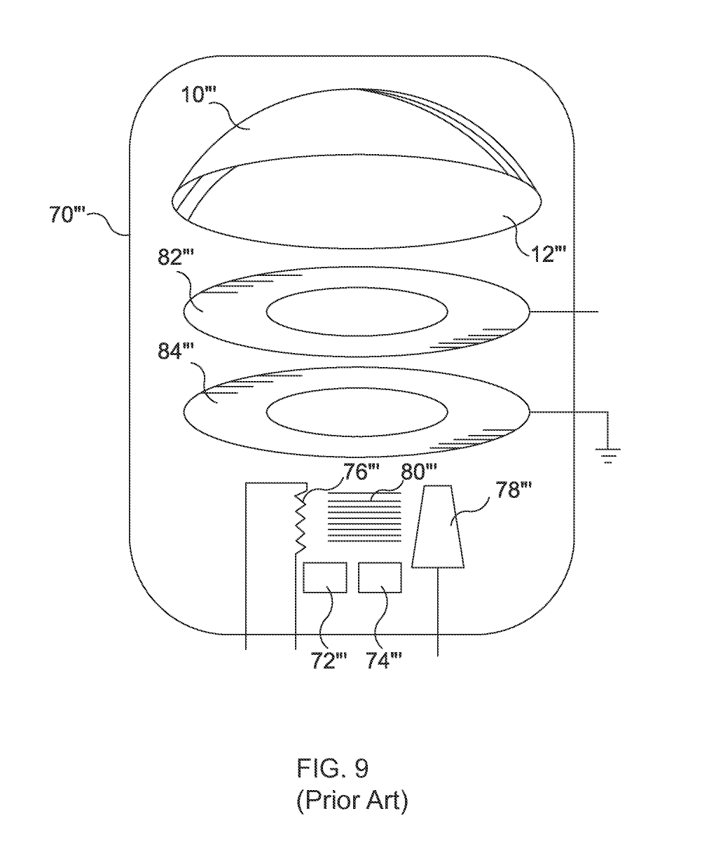

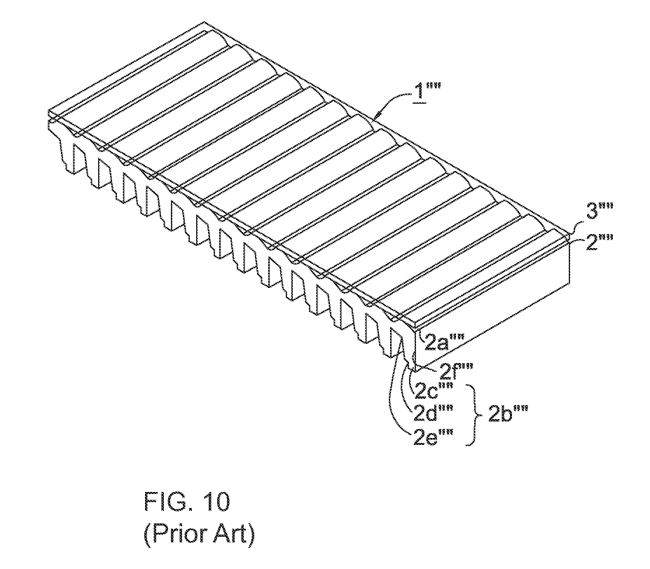

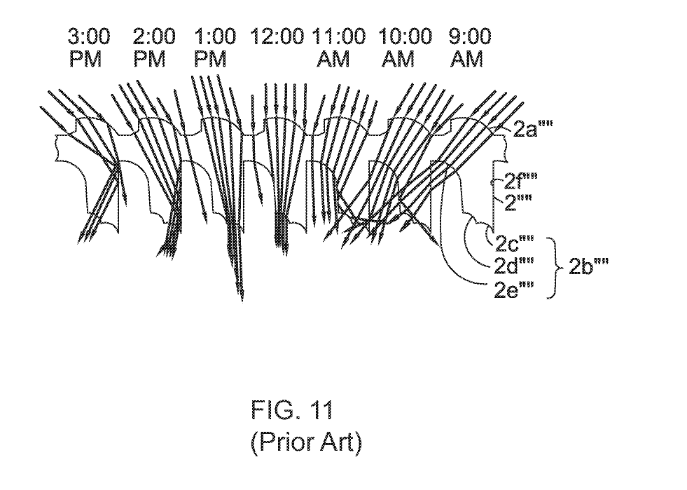

With reference to FIGS. 4A and 4B for a micro-structured lens of a system for switching a focus position in accordance with a second and third preferred embodiment of the present invention respectively, the micro-structure/micro-structure layer is primarily a Fresnel lens structure, and the first preferred embodiment has been disclosed in FIGS. 2A, 2B, 3A, 3B, 3C, 3D. The micro-structures/micro-structure layers of the second and third preferred embodiments are continuous or multi-stage Kinoform Fresnel structures.

In addition, if the physical structure of the related devices/components such as the curvature can be changed, then sunlight can be focused at the plurality of objects to be focused such as the solar battery and the heating pipe to improve the energy conversion efficiency.

In summation of the description above, the system for switching a focus position of the present invention has the following advantages:

1. In the environment with the same light source (or sunlight condition), the present invention can convert light energy into electrical energy and heat energy at the same time to improve the efficiency of collecting light energy (or solar energy).

2. In the environment with the same light source (or sunlight condition), the present invention can selectively convert the light energy (or solar energy) into electrical energy or heat energy, as required.

3. In the environment with the same light source (or sunlight condition), the present invention can maintain a natural light condition without converting the light energy (or solar energy) into electrical energy or heat energy.

In view of the aforementioned advantages and features, the system for switching a focus position of the present invention can be used extensively in our daily life, particularly for the energy saving and carbon reduction measures promoted by the green energy and environmental protection organizations. For example, the daily life of an American family is closely related to electrical and heat energies, and the present invention can collect the solar energy provided by the nature and convert the solar energy into the electrical and heat energies required in our life. In addition, when it is not necessary to collect the solar energy, the present invention also allows sunlight to enter into our home to maintain a natural light condition, and the way of converting natural energy into usable energy required in our life is the best way for energy saving and environmental protection.

In summation of the description above, the present invention improves over the prior art and complies with the patent application requirements, and thus is duly file for patent application. While the invention has been described by means of specific embodiments, numerous modifications and variations could be made thereto by those skilled in the art without departing from the scope and spirit of the invention set forth in the claims.

What is claimed is:

1. A system for switching a focus position, comprising:
at least one active focus-switch device, capable of changing a focal length for several times;
a plurality of objects to be focused, having a plurality of exit light beams focused thereon after the plurality of incident light beams pass through the active focus-switch devices; and
at least one external power supply, electrically coupled to active focus-switch device;
wherein the external power supply is conducted or not conducted to the active focus-switch devices, and the active focus-switch devices can focus the plurality of exit light beams on the plurality of objects to be focused, or can form the plurality of exit light beams parallel to the plurality of incident light beams, after the plurality of incident light beams pass through the active focus-switch devices.

2. The system for switching a focus position as recited in claim 1, wherein the active focus-switch device comprises:
at least one focus-switch layer; and
at least one micro-structure layer, covered onto the micro-structure layer.

3. The system for switching a focus position as recited in claim 2, wherein the focus-switch layer is made of a material selected from the collection of a polymer dispersed liquid crystal (PDLC) and a bistable liquid crystal.

4. The system for switching a focus position as recited in claim 2, wherein the micro-structure layer is a Fresnel lens structure.

5. The system for switching a focus position as recited in claim 2, wherein the focus-switch layer is covered onto the micro-structure layer by a coating process or a perfusion process.

6. A system for switching a focus position, comprising:
at least one active focus-switch device, including a first active focus-switch lens and a second active focus-switch lens, for changing a focal length for at least three times;
at least one first object to be focused, having a plurality of first exit light beams focused thereon after the plurality of incident light beams pass through the active focus-switch devices;
at least one second object to be focused, having a plurality of second exit light beams focused thereon after the plurality of incident light beams pass through the active focus-switch devices; and
at least one external power supply, electrically coupled to active focus-switch device;
wherein the external power supply is conducted or not conducted to the active focus-switch devices, and the active focus-switch devices focus the plurality of first exit light beams at the first object to be focused, or the plurality of second exit light beams are focused at the second object to be focused, or after the plurality of incident light beams pass through the active focus-switch devices, a plurality of third exit light beams parallel to the plurality of incident light beams are emitted.

7. The system for switching a focus position as recited in claim 6, wherein the first active focus-switch lens comprises a first focus-switch layer and a first micro-structure layer, and the first focus-switch layer is covered onto the first micro-structure layer, and the second active focus-switch lens comprises a second focus-switch layer; and a second micro-structure layer, and the second focus-switch layer is covered onto the second micro-structure layer.

8. The system for switching a focus position as recited in claim 7, wherein the first focus-switch layer and the second focus-switch layer are made of a material selected from the collection of a polymer dispersed liquid crystal (PDLC) and a bistable liquid crystal.

9. The system for switching a focus position as recited in claim 7, wherein the first micro-structure layer and the second micro-structure layer are Fresnel lens structures.

10. The system for switching a focus position as recited in claim 7, wherein the first focus-switch layer and second focus-switch layer are covered onto the first micro-structure layer and the second micro-structure layer respectively by a coating process or a perfusion process.

11. The system for switching a focus position as recited in claim 6, wherein the first object to be focused is a solar battery for converting solar energy into electrical energy.

12. The system for switching a focus position as recited in claim 6, wherein the second object to be focused is a heating pipe for converting solar energy into heat energy.

13. The system for switching a focus position as recited in claim 7, wherein when the external power supply is not conducted to the first active focus-switch lens and conducted to the second active focus-switch lens, the second exit light beam is focused at the second object to be focused.

14. The system for switching a focus position as recited in claim 7, wherein when the external power supply is conducted to the first active focus-switch lens and not conducted to the second active focus-switch lens, the first exit light beam is focused at the first object to be focused.

15. The system for switching a focus position as recited in claim 7, wherein when the external power supply is conducted to both of the first active focus-switch lens and the second active focus-switch lens, a plurality of third exit light beams parallel to the incident light beam are produced.
